(19) United States
(12) Patent Application Publication
(10) Pub. No.: US 2009/0057916 A1
(43) Pub. Date: Mar. 5, 2009

(54) SEMICONDUCTOR PACKAGE AND APPARATUS USING THE SAME

(75) Inventors: Kun-Dae YEOM, Chungcheongnam-do (KR); Sang-Wook PARK, Chungcheongnam-do (KR); Sung-Ki LEE, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/198,731

(22) Filed: Aug. 26, 2008

(30) Foreign Application Priority Data
Aug. 30, 2007 (KR) 10-2007-0087780

(51) Int. Cl. H01L 23/49

(52) U.S. Cl. 257/777; 257/E23.024

(57) ABSTRACT

A semiconductor package is provided. The semiconductor package comprises a substrate having a top surface and a bottom surface, a first semiconductor chip having a plurality of bonding pad regions electrically connected to the substrate by a plurality of first bonding wires, a spacer tape covering the active surface of the first semiconductor chip excluding the plurality of bonding pad regions, and a second semiconductor chip mounted on the active surface of the first semiconductor chip with the spacer interposed.

### CROSS-REFERENCE TO RELATED APPLICATIONS

This application claims priority under 35 U.S.C §119 to Korean Patent Application No. 10-2007-0087780, filed on Aug. 30, 2007 in the Korean Patent Office, the entire contents of which are incorporated by reference.

### BACKGROUND

The present inventive concept is related to a semiconductor package, and more particularly, a semiconductor package with improved mechanical durability and an apparatus using the same.

Due to recent demand for miniaturization in electronic devices, the sizes of the semiconductor packages in the electronic devices are becoming smaller, thinner and lighter. Generally, a semiconductor package includes a single semiconductor chip. However, in more recent semiconductor packages a structure for mounting a plurality of semiconductor chips is being developed. Such a multi-chip semiconductor package should include thinner semiconductor chips so that a plurality of semiconductor chips may be mounted in as small of a package as possible.

Also, when a plurality of semiconductor chips are stacked, there may be an overhang region when an upper semiconductor chip is larger in one or more dimensions than a lower chip. In the case that the overhanging length of the edge of the semiconductor chip is large, stress may be generated during a wire bonding process, thereby causing deformity in the semiconductor chip. Further, damage to the semiconductor chip, such as a crack, may occur. The likelihood of damage to the semiconductor chips due to overhanging length is increased as the semiconductor chips are made thinner. Therefore, when stacking thin semiconductor chips, making the overhanging length shorter is one way to reduce chip deformity and damage to the semiconductor chips.

### SUMMARY

Exemplary embodiments of the present inventive concept are related to semiconductor packages. In an exemplary embodiment, a semiconductor package may include a first semiconductor chip having a plurality of bonding pad regions on a top surface thereof; a second semiconductor chip mounted on the top surface of the first semiconductor chip; and a spacer between the first and second semiconductor chips, the spacer covering a top surface of the first semiconductor chip excluding the bonding pad regions.

### BRIEF DESCRIPTION OF THE DRAWINGS

The accompanying drawings are included to provide a further understanding of the inventive concept, and are incorporated in and constitute a part of this specification. The drawings illustrate example embodiments of the present inventive concept and, together with the description, serve to explain principles of the present inventive concept. In the drawings:

FIG. 1A is a plan view illustrating an exemplary semiconductor package according to an embodiment of the present inventive concept;

FIG. 1B is a cross-sectional view taken along the line I-I of FIG. 1A;

FIG. 1C is a cross-sectional view taken along the line II-II of FIG. 1A;

FIG. 1D is a plan view illustrating another exemplary semiconductor package according to an embodiment of the present inventive concept;

FIG. 2A is a plan view illustrating a modified exemplary semiconductor package according to an embodiment of the present inventive concept;

FIG. 2B is a cross-sectional view taken along the line I-I of FIG. 2A;

FIG. 2C is a cross-sectional view taken along the line II-II of FIG. 2A;

FIG. 2D is a plan view illustrating another modified exemplary semiconductor package according to an embodiment of the present inventive concept; and

FIG. 3 is a perspective view illustrating an exemplary electronic apparatus comprising an exemplary semiconductor package according to embodiments of the present inventive concept.

### DETAILED DESCRIPTION OF THE EMBODIMENTS

The present inventive concept will now be described more fully hereinafter with reference to the accompanying drawings, in which preferred embodiments of the inventive concept are shown. This inventive concept, however, may be embodied in many different forms and should not be construed as limited to the embodiments set forth herein. Rather, these embodiments are provided so that this disclosure will be thorough and complete, and will fully convey the scope of the inventive concept to those skilled in the art. Any element in a claim that does not explicitly state “means for” performing a specified function, or “step for” performing a specific function, is not to be interpreted as a “means” or “step” clause as specified in 35 U.S.C. §112, paragraph 6. In particular, the use of “step of” in the claim herein is not intended to invoke the provisions of 35 U.S.C. §112, paragraph 6. In the drawings, the thicknesses of layers and regions are exaggerated for clarity. It will also be understood that when a layer is referred to as being “on” another layer or substrate, it can be directly on the other layer or substrate, or intervening layers may also be present. Like reference numbers refer to like elements throughout.

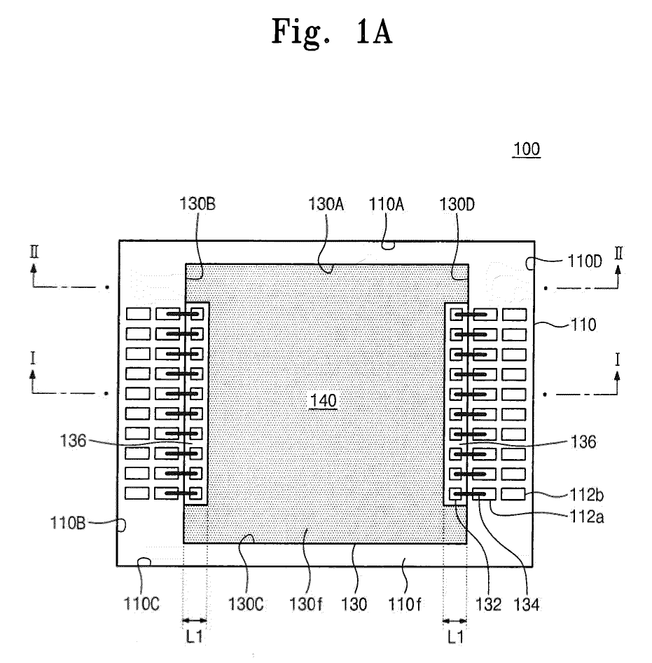

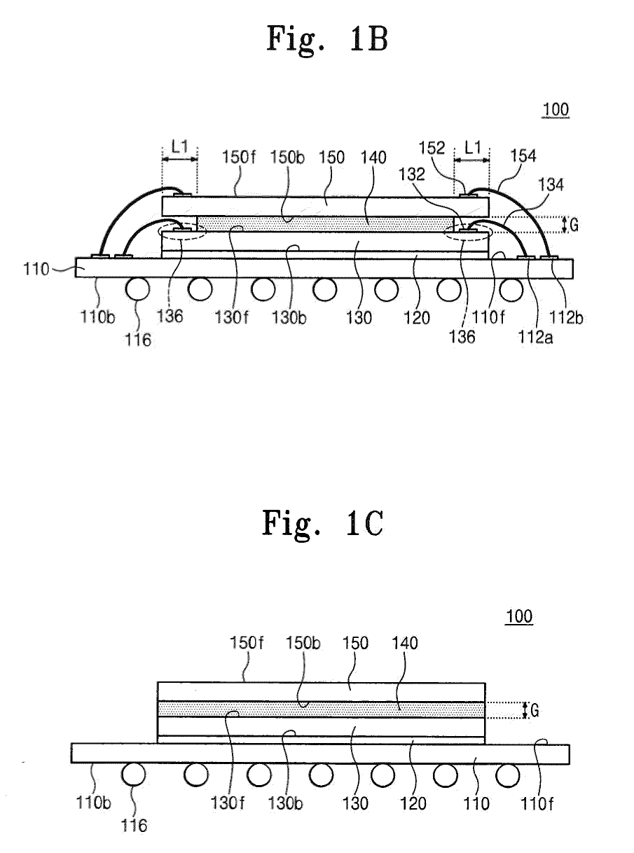

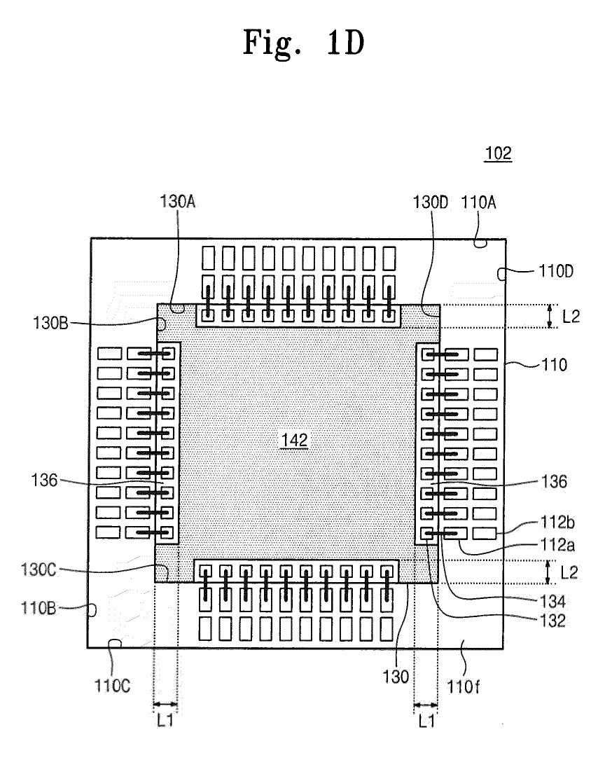

FIG. 1A is a plan view illustrating an exemplary embodiment of a semiconductor package according to the present inventive concept, FIG. 1B is a cross-sectional view taken along the line I-I of FIG. 1A, and FIG. 1C is a cross-sectional view taken along the line II-II of FIG. 1A.

Referring to FIG. 1A to FIG. 1C, in an exemplary semiconductor package 100, a first semiconductor chip 130 and a second semiconductor chip 150 may be stacked on a substrate 110, e.g., a printed circuit board (PCB). The first semiconductor chip 130 and the second semiconductor chip 150 may be equal-sized chips having the same or different functionality. In FIG. 1A, the second semiconductor chip 150 is not shown for ease of illustration.

The substrate 110 may have a rectangular or square shape in which a top side edge 110A and a bottom side edge 110C are opposite each other, and a left side edge 110B and a right side edge 110D are opposite each other. On a top surface 110f of the substrate 110, a plurality of first substrate pads 112a may be disposed in a line along the left side edge 110B and the right side edge 110D, respectively. Similarly, a plurality of second substrate pads 112b may be disposed in a line adjacent to the plurality of first substrate pads 112a. The first substrate pads 112a and the second substrate pads 112b may be disposed substantially parallel to each other. Alternatively, each of the second substrate pads 112a may be disposed in between corresponding ones of the first substrate pads 112a. A plurality of connection terminals 116, such as solder balls, may be bonded to a bottom surface 110b of the substrate 110.

The first semiconductor chip 130 is mounted on the top surface 110f of the substrate 110. The first semiconductor chip 130 may have an active surface 130f and an inactive surface 130b. The inactive surface 130b may face the top surface 110f of the substrate 110. An adhesive layer 120 may be interposed between the inactive surface 130b and the top surface 110f. The adhesion layer 120 may be insulative. The first semiconductor chip 130 may have a rectangular or square shape in which a top side edge 130A and a bottom side edge 130C are opposite each other, and a left side edge 130B and a right side edge 130D are opposite each other.

On the active surface 130f of the first semiconductor chip 130, a plurality of first wire bonding pads 132 may be disposed in a line along the left side edge 130B and the right side edge 130D, respectively. The plurality of first wire bonding pads 132 may be concentrated near the edges of the active surface 130f to form bonding pad regions 136 in portions of the left side edge 130B and the right side edge 130D. In other words, the bonding pad regions may extend partially along edges of the active surface 130f. The plurality of first wire bonding pads 132 and the plurality of first substrate pads 112a may be electrically connected to each other by a plurality of first bonding wires 134 so that the first semiconductor chip 130 is electrically connected to the substrate 110. Each of the first wire bonding pads 132 may be a redistributed pad. In other words, each of the first wire bonding pads 132 may be redistributed from a chip pad that is disposed elsewhere on the active surface 130f of the first semiconductor chip 130.

The second semiconductor chip 150 is mounted on the first semiconductor chip 130. The second semiconductor chip 150 may have an active surface 150f and an inactive surface 150b. The inactive surface 150b may face the active surface 130f of the first semiconductor chip 130. The second semiconductor chip 150 may have an identical or similar structure to that of the first semiconductor chip 130. A plurality of second wire bonding pads 152 may be provided on the active surface 150f of the second semiconductor chip 150. Similar to the first wire bonding pads 132, the plurality of second wire bonding pads 152 may be concentrated near the edges of the active surface 150f. Accordingly, a plurality of wire bonding pad regions, similar to the bonding pad regions 136, may be formed near the edges of the active surface 150f. The plurality of second wire bonding pads 152 and the second substrate pads 112b may be electrically connected to each other by the second bonding wires 154 so that the second semiconductor chip 150 is electrically connected to the substrate 110. Each of the second wire bonding pads 152 may be a redistributed pad. The first and second semiconductor chips 130 and 150 may be electrically connected to each other by means of the substrate 110.

A spacer tape 140 is interposed between the inactive surface 150b of the second semiconductor chip 150 and the active surface 130f of the first semiconductor chip 130. The spacer tape 140 may serve as an adhesive layer bonding the first semiconductor chip 130 and the second semiconductor chip 150 together. Also, the spacer tape 140 may serve to maintain an interval G between the first semiconductor chip 130 and the second semiconductor chip 150, to provide room for the plurality of first bonding wires 134. Accordingly, physical contact between the first bonding wires 134 and the inactive surface 150b of the second semiconductor chip 150 may be avoided. Thus, electrical malfunction of the semiconductor package 100 due to such contact may be prevented.

The spacer tape 140 has a structure which covers the active surface 130f excluding the bonding pad regions 136. The spacer tape 140 may have an irregular structure so that it does not cover the bonding pad regions 136. As used here, an irregular structure is a structure that is not a rectangular or square. The spacer tape 140 may be fabricated using a punch die, which can produce an irregular shaped spacer tape 140. The spacer tape 140 may be made of an organic material, for example, polyimide.

The second semiconductor chip 150, as shown in FIG. 1B, may have an overhang L1 along the line I-I because the wire bonding regions 136 are not covered by the spacer tape 140. On the other hand, as shown in FIG. 1C, the overhang L1 is not present along the line II-II because the spacer tape 140 fills the entire gap between the first semiconductor chip 130 and the second semiconductor chip 150. As a result, the stacked structure of the first and second semiconductor chips 130 and 150 does not have an overhang except above the bonding pad regions 136. Accordingly, defects such as chip deformities or cracks, which are primarily due to stress or physical impact that may be put on the second semiconductor chip 150 during a process of forming the second bonding wires 154, of the semiconductor package 100 may be minimized and/or eliminated. The spacer tape 140 may be particularly useful in the case that the first and second semiconductor chips 130 and 150 are very thin.

FIG. 1D is a plan view illustrating a modification of FIG. 1A.

Referring to FIG. 1D, a modified semiconductor package 102 may have the second semiconductor chip 150 stacked on the first semiconductor chip 130. The first semiconductor chip 130 may have two additional bonding pad regions 136 disposed along the top side edge 130A and the bottom side edge 130C of the first semiconductor chip 130. Also, the second semiconductor chip 150 may have two additional bonding pad regions along edges of the active surface 150f adjacent to the top side edge 130A and the bottom side edge 130C of the first semiconductor chip 130.

The substrate 110 may have two additional sets of first substrate pads 112a on the top surface 110f along the top side edge 110A and the bottom side edge 110C, respectively. Moreover, the substrate 110 may have two additional sets of second substrate pads 112b adjacent to the plurality of first substrate pads 112a along the top side edge 110A and the bottom side edge 110C.

A spacer tape 142 may be interposed between the first semiconductor chip 130 and the second semiconductor chip 150. The spacer tape 142 may have a structure in which all four side edges are irregular. In other words, the four side edges may not form a rectangle or square. Therefore, the second semiconductor chip 150 may have two more overhangs L2. The length of L2 may be equal to or different from that of L1.

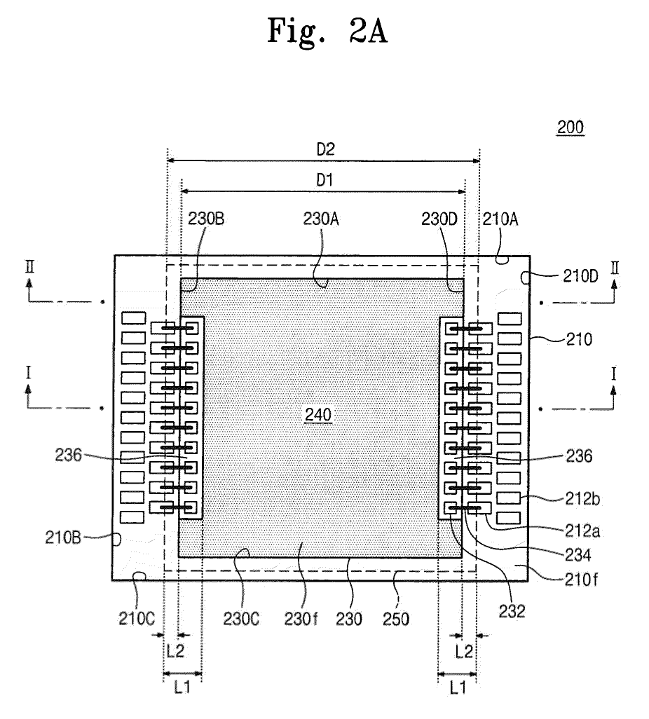

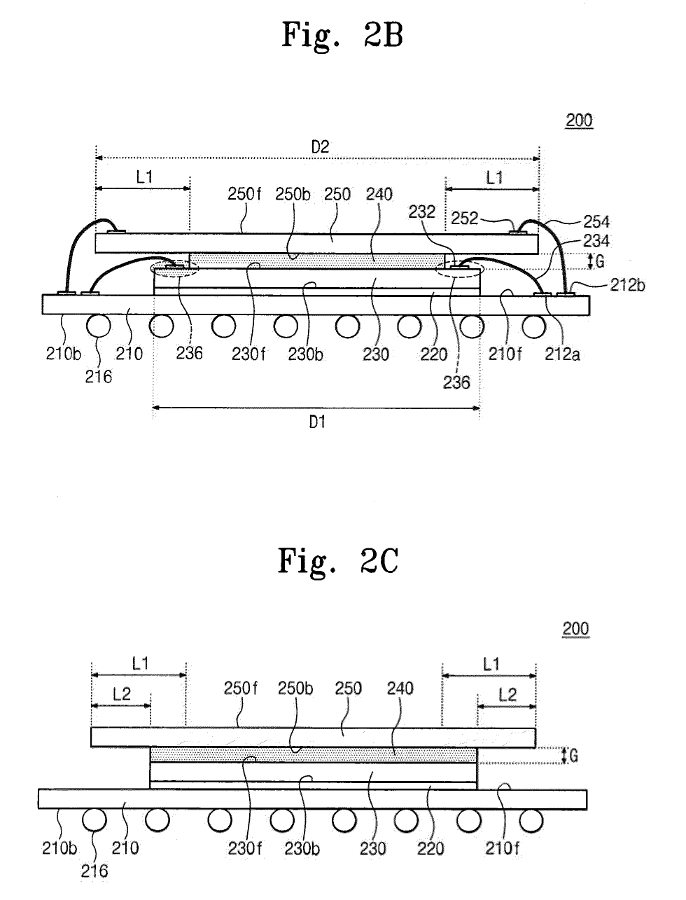

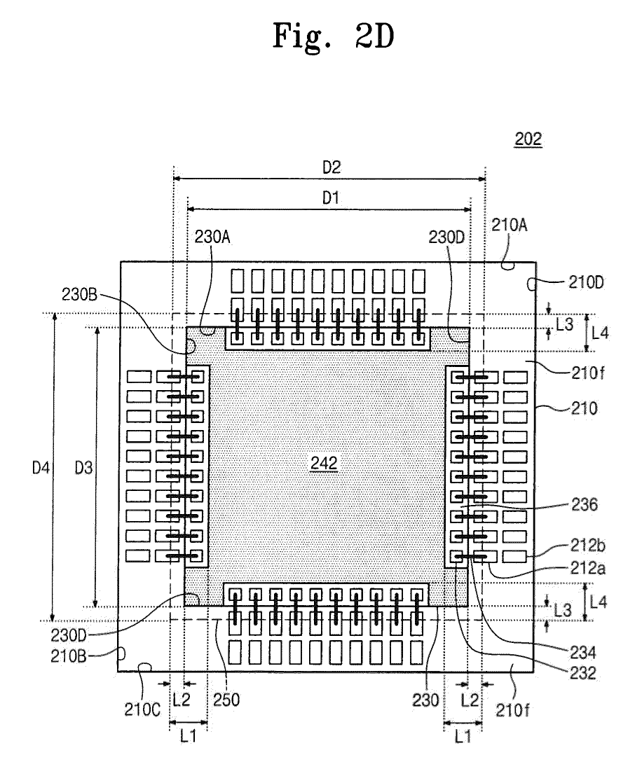

FIG. 2A is plan view illustrating a modified exemplary semiconductor package according to the present inventive concept, FIG. 2B is a cross-sectional view taken along the line I-I of FIG. 2A, and FIG. 2C is a cross-sectional view taken along the line II-II of FIG. 2A.

Referring to FIG. 2A to FIG. 2C, the semiconductor package 200 may have a first semiconductor chip 230 and a second semiconductor chip 250 stacked on a substrate 210 such as a PCB. The first semiconductor chip 230 and the second semiconductor chip 250 may be chips of different sizes. For example, the first semiconductor chip 230 may have a first width D1, and the second semiconductor chip 250 may have a second width D2 which is larger than the first width D1. The first semiconductor chip 230 and the second semiconductor chip 250 may be of the same kind or of different kinds (i.e., may have the same functionality or different functionality).

The substrate 210 may be a rectangular or square shape in which the top side edge 210A and the bottom side edge 210C are opposite each other and the left side edge 210B and the right side edge 210D are opposite each other. A plurality of the first substrate pads 212a may be disposed in a line along each of the left side edge 210B and the right side edge 210D on a top surface 210f of the substrate 210. The first substrate pads 210a and the second substrate pads 212b may be disposed substantially parallel to each other, or each of the second substrate pads 212b may be disposed between corresponding ones of the substrate pads 212a. A plurality of connecting terminals 216, such as solder balls, may be bonded to a bottom surface 210b of the substrate 210.

The first semiconductor chip 230 is mounted on the top surface 210f of the substrate 210. The first semiconductor chip 230 may have an active surface 230f and an inactive surface 230b. The inactive surface 230b may face the top surface 210f. An insulative adhesive layer 220 may be interposed between the inactive surface 230b and the top surface 210f. The first semiconductor chip 230 may have a rectangular or square shape in which the top side edge 230A and the bottom side edge 230C are opposite each other and the left side edge 230B and the right side edged are opposite each other. A plurality of first wire bonding pads 232 may be disposed along the left side edge 230B and the right side edge 230D on the active surface 230f of the first semiconductor chip 230. The plurality of first wire bonding pads 232 may be concentrated near the edges of the active surface 230f to form a plurality of bonding pad regions 236 in portions of the left side edge 230B and the right side edge 230D, respectively. The plurality of first wire bonding pads 232 and the plurality of first substrate pads 212a are electrically connected by a plurality of first bonding wires 234. Accordingly, the first semiconductor chip 230 is electrically connected to the substrate 210. Each of the first wire bonding pads 232 may be a redistributed pad.

The second semiconductor chip 250 is mounted on the first semiconductor chip 230. The second semiconductor chip 250 has a larger width D2 than the first semiconductor chip 230 so that the second semiconductor chip 250 may completely cover the first semiconductor chip 230. The second semiconductor chip 250 may have an active surface 250f and an inactive surface 250b. The inactive surface 250b of the second semiconductor chip 250 may face the active surface 230f of the first semiconductor chip 230. A plurality of second wire bonding pads 252 may be provided on the active surface 250f of the second semiconductor chip 250. A plurality of second wire bonding pads 252 may be disposed near the edges of the active surface 250f. Accordingly, similar to the first semiconductor chip 230, the second semiconductor chip 250 may have a plurality of bonding pad regions near edges of the active surface 250f. The plurality of second wire bonding pads 252 and the plurality of second substrate pads 212b may be electrically connected to each other by a plurality of second bonding wires 254. Accordingly, the second semiconductor chip 250 may be electrically connected to the substrate 210. Each of the second wire bonding pads 252 may be a redistributed pad.

A spacer tape 240 may be interposed between the inactive surface 250b of the semiconductor chip 250 and the active surface 230f of the first semiconductor chip 230. The spacer tape 240 may be made of a material such as polyimide, and may be fabricated using a punch die. The spacer tape 240 may serve as an adhesive layer that bonds the first semiconductor chip 230 and the second semiconductor chip 250 together. Also, the spacer tape 240 may serve to maintain an interval G between the first semiconductor chip 230 and the second semiconductor chip 350, to provide room for the plurality of first bonding wires 234. Accordingly, physical contact between the first bonding wires 234 and the inactive surface 250b of the second semiconductor chip 250 may be avoided. Thus, electrical malfunction of the semiconductor package 200 due to such contact may be prevented.

The spacer tape 240 may include, for example, an irregular structure which covers the active surface 230f excluding the bonding pad regions 236. The second semiconductor chip 250, as shown in FIG. 2B, may have a first overhang L1 along the line I-I because the bonding pad regions 236 are not covered by the spacer tape 240. However, as shown in FIG. 2C, the second semiconductor chip 250 may have a second overhang L2 along the line II-II shorter than the first overhang L1. As a result, the stacked structure of the first and the second semiconductor chips 230 and 250 may have a relatively longer first overhang L1 in the bonding pad regions 236 but may have a relatively shorter second overhang L2 in the regions except for the bonding pad regions 236.

FIG. 2D is a plan view illustrating a modification of the embodiment of FIG. 2A.

Referring to FIG. 2D, a modified semiconductor package 202 may have the second semiconductor chip 250 stacked on the first semiconductor chip 230. The second semiconductor chip 250 may be bigger than the first semiconductor chip 250 so that the second semiconductor chip 250 may completely cover the first semiconductor chip 230. For example, the first semiconductor chip 230 may cover an area of D1 by D3, and the second semiconductor chip 250 may cover an area of D2 by D4. D2 and D4 may be greater than D1 and D3, respectively. D1 and D3 may be equal or different in length, D2 and D4 may be the same.

The first semiconductor chip 230 may have two additional sets of bonding pad regions 236 along the top side edge 230A and the bottom side edge 230C of the first semiconductor chip 230, respectively. Also, the second semiconductor chip may have two additional sets of bonding pad regions along edges of the active surface 250f adjacent to the top side edge 230A and the bottom side edge 230C of the first semiconductor chip 230.

There are also two additional sets of first substrate pads 212a along the top side edge 210A and the bottom side edge 2101B, respectively, of the substrate 210. The substrate 210 may have two additional sets of second substrate pads 212b adjacent to the plurality of first substrate pads 212a along the top side edge 210A and the bottom side edge 21.

A spacer tape 242 may be interposed between the first semiconductor chip 230 and the second semiconductor chip 250. The spacer tape 242 may have a structure in which all four side edges are irregular. Therefore, the second semiconductor chip 250 may have a shorter overhang L3 and a longer overhang L4. The length of L3 may be equal to or different from that of L2, and the length of L4 may be equal to or different from that of L1.

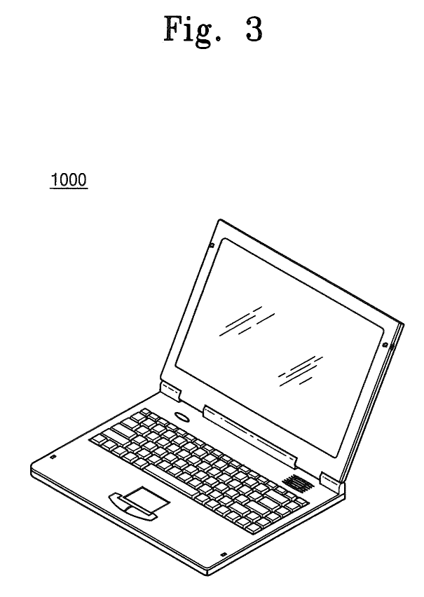

FIG. 3 is a perspective view illustrating an exemplary electronic apparatus comprising an exemplary semiconductor package according to embodiments of the present inventive concept.

According to FIG. 3, any one of the semiconductor packages 100, 102, 200 and 202 may be used in an electronic apparatus 1000 such as a laptop computer. The electronic apparatus 1000 may include a cell-phone, an MP3 player, a memory card, a liquid crystal display, a plasma display panel, a portable media player, a camcorder, and many other electronic apparatuses.

According to the present inventive concept, the spacer tape in a semiconductor package covers the active surface of a lower semiconductor chip except the bonding wire region; thereby the overhang may be removed or minimized. If the overhang is removed or minimized, damage or cracks of the upper semiconductor chip resulting from stress applied during a bonding wire process may be prevented and yield may be enhanced so as to improve durability of the semiconductor package.

In an exemplary embodiment, a semiconductor package may include a first semiconductor chip having a plurality of bonding pad regions on a top surface thereof; a second semiconductor chip mounted on the top surface of the first semiconductor chip; and a spacer between the first and second semiconductor chip, the spacer covering a top surface of the first semiconductor chip excluding the bonding pad regions.

In another exemplary embodiment, a semiconductor package may include a substrate having a top surface and a bottom surface; a first semiconductor chip mounted on the top surface of the substrate and electrically connected to the substrate through a plurality of first bonding wires, the first semiconductor chip comprising an active surface including a plurality of bonding pad regions; a second semiconductor chip mounted on the active surface of the first semiconductor chip; and a spacer between the first and second semiconductor chips, the spacer covering the active surface excluding the plurality of bonding pad regions.

Although the present inventive concept has been described in connection with the embodiments of the present inventive concept illustrated in the accompanying drawings, it is not limited thereto. It will be apparent to those skilled in the art that various substitutions, modifications and changes may be made thereto without departing from the scope and spirit of the inventive concept.

What is claimed is:

1. A semiconductor package comprising:
a first semiconductor chip having at least one bonding pad region on a top surface thereof, the bonding pad region extending along a partial length of at least one side of the top surface of the first semiconductor chip;
a second semiconductor chip mounted on the top surface of the first semiconductor chip; and
a spacer disposed between the first and second semiconductor chips, the spacer covering the top surface of the first semiconductor chip excluding the bonding pad region.

2. The semiconductor package as claimed in claim 1, wherein the at least one bonding pad region comprises a plurality of bonding pad regions and wherein the plurality of bonding pad regions extend along partial lengths of at least two sides of the first semiconductor chip.

3. The semiconductor package as claimed in claim 2, wherein each of the bonding pad regions comprises a plurality of wire bonding pads to which a plurality of bonding wires are electrically connected.

4. The semiconductor package as claimed in claim 3, wherein the plurality of wire bonding pads are redistributed pads.

5. The semiconductor package as claimed in claim 3, wherein the spacer comprises an irregular shape such that the spacer does not cover the plurality of bonding pad regions.

6. The semiconductor package as claimed in claim 5, wherein the spacer provides sufficient space for the plurality of bonding wires between the first and the second semiconductor chips.

7. The semiconductor package as claimed in claim 6, wherein the spacer is an adhesive layer to adhere the second semiconductor chip to the first semiconductor chip.

8. The semiconductor package as claimed in claim 6, wherein a size of the second semiconductor chip is equal to or greater than a size of the first semiconductor chip.

9. A semiconductor package comprising:
a substrate having a top surface and a bottom surface;
a first semiconductor chip mounted on the top surface of the substrate and electrically connected to the substrate through a plurality of first bonding wires, the first semiconductor chip comprising an active surface including a plurality of bonding pad regions extending partially along sides of the active surface of the first semiconductor chip;
a second semiconductor chip mounted on the first semiconductor chip; and
a spacer disposed between the first and second semiconductor chips, the spacer covering the active surface of the first semiconductor chip excluding the plurality of bonding pad regions.

10. The semiconductor package as claimed in claim 9, wherein each of the bonding pad regions comprises a plurality of bonding pads electrically connected to the plurality of first bonding wires.

11. The semiconductor package as claimed in claim 10, wherein the plurality of bonding pads are redistributed pads.

12. The semiconductor package as claimed in claim 10, wherein edges of the spacer are irregular so that the spacer does not cover the plurality of bonding pad regions.

13. The semiconductor package as claimed in claim 9, wherein the spacer provides sufficient space for the plurality of first bonding wires between the first and the second semiconductor chips such that the first bonding wires do not contact the second semiconductor chip.

14. The semiconductor package as claimed in claim 13, wherein the spacer is an adhesive layer to adhere the first and the second semiconductor chips together.

15. The semiconductor package as claimed in claim 14, wherein the spacer includes polyimide.

16. The semiconductor package as claimed in claim 9, wherein the second semiconductor chip is substantially the same size as the first semiconductor chip.

17. The semiconductor package as claimed in claim 16, wherein the second semiconductor chip comprises an overhang structure above the plurality of bonding pad regions of the first semiconductor chip, and does not comprise an overhang structure above remaining portions of the active surface of the first semiconductor chip.

18. The semiconductor package as claimed in claim 9, wherein the second semiconductor chip is a larger size than the first semiconductor chip.

19. The semiconductor package as claimed in claim 18, wherein the second semiconductor chip comprises a first overhang structure of a first length above the plurality of bonding pad regions of the first semiconductor chip, and comprises a second overhang structure of a second length shorter than the first length above remaining portions of the active surface of the first semiconductor chip.

20. The semiconductor package as claimed in claim 9, wherein the substrate comprises a plurality of first substrate pads on the top surface thereof, the plurality of first substrate pads electrically connected to the plurality of first bonding wires.

21. The semiconductor package as claimed in claim 9, wherein the second semiconductor chip is electrically connected to the substrate by a plurality of second bonding wires.

22. The semiconductor package as claimed in claim 21, wherein the substrate comprises a plurality of second substrate pads on the top surface thereof, the plurality of second substrate pads electrically connected to the plurality of second bonding wires.

23. The semiconductor package as claimed in claim 9, wherein the substrate comprises a plurality of external terminals on the bottom surface thereof.
